(19) United States
(12) Patent Application Publication
(10) Pub. No.: US 2007/0228442 A1
(43) Pub. Date: Oct. 4, 2007

(54) Thin Film Capacitor, Method for Forming Same, and Computer Readable Recording Medium

(75) Inventor: Akinobu Kakimoto, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/574,939

(22) PCT Filed: Sep. 9, 2005
(86) PCT No.: PCT/JP05/16639

§ 371 Date: Mar. 8, 2007

(30) Foreign Application Priority Data
Sep. 9, 2004 (JP) 2004-262668

(51) Int. Cl. H01L 29/76; H01L 21/8242; H03K 17/687

(52) U.S. Cl. 257/310; 438/240; 257/E29.227; 257/E29.229; 257/E21.65; 257/E21.653

(57) ABSTRACT

In a thin film capacitor, reducing a leak current by suppressing concentration of an electric filed. Forming a zirconium oxide layer (26A) on a lower electrode (22) made of a conductive material. Forming a buffer layer (28) made of an amorphous material on the first zirconium oxide layer (26A). Forming a second zirconium oxide layer (26B) on the buffer layer (28), and forming an upper electrode (24) made of a conductive material on the second zirconium oxide layer (26B)

### TECHNICAL FIELD

The present invention relates to thin film capacitors and, more particularly, to a structure of a thin film capacitor using a zirconium oxide or a hafnium oxide formed on a semiconductor substrate.

### BACKGROUND ART

When forming a thin film capacitor as a passive element in a semiconductor device, a silicon oxide (SiO) a silicon nitride (SiN), an aluminum oxide (AlO), a zirconium oxide (ZrO), a hafnium oxide (HfO), etc. are used as dielectric materials. Among those dielectric materials, an oxide of zirconium (zirconium oxide) and an oxide of hafnium (hafnium oxide) especially have a large dielectric constant and suitable for forming a small and thin film capacitor of a large capacity.

The thin film capacitor formed by a zirconium oxide (hereinafter, referred to as ZrO thin film capacitor) is formed in a multi-layer structure of a semiconductor device by depositing a ZrO film of a thickness of about 10 nm by using an ALD (Atomic Layer Deposition) method and then forming an upper electrode of TiN thereon.

Additionally, the thin film capacitor formed by a hafnium oxide (hereinafter, referred to as an HfO thin film capacitor) is formed by depositing an HfO film of a thickness of about 10 nm by using an ALD method and then forming an upper electrode of TiN thereon.

As mentioned above, zirconium and hafnium are used in many cases as a capacitor material or an insulating material. For examples it is suggested to use a ZrO₂ film of a high dielectric constant as a gate insulation layer of a MOSFET (for example, refer to Patent Document 1).

Patent Document 1: Japanese Laid-Open Patent Application No. 2003-151976

### DISCLOSURE OF THE INVENTION

### Problems to be Solved by the Invention

Since the zirconium oxide ZrO₂ has a particularly high dielectric constant in zirconium and film deposition can be made at a low temperature of amount 250° C., it is suitable for a material of a thin film capacitor. However, a ZrO₂ film increases in a surface roughness (surface mophorogy) when crystallization progresses, and there is a problem in that a leak current increases when functions as a capacitor. That is, if a surface roughness of a ZrO₂ film increases, an electric field concentration increases in an interface between an electrode layer and the ZrO₂ film (that is a surface of the ZrO₂ film having a large surface roughness), thereby increasing a leak current.

Additionally, the same occurs in a hafnium oxide HfO₂ which is an oxide of Hafnium, and when crystallization progresses, a surface roughness (surface mophorogy) increases and there is a problem in that a leak current increases when functioning as a capacitor.

The present invention was made in view of the above-mentioned problems, and it is an object to provide a thin film capacitor using a zirconium oxide or a hafnium oxide in which an electric filed concentration is suppressed and a leak current is reduced.

### Means to Solve the Problem

In order to achieve the above-mentioned objects, there is provided according to one aspect of the present invention a thin film capacitor formed with a zirconium oxide or a hafnium oxide as a dielectric material, comprising: a lower electrode made of a conductive material; a first dielectric layer formed on the lower electrode; a buffer layer formed on the first dielectric layer; a second dielectric layer formed on the buffer layer; and an upper layer formed on the second dielectric layer and made of a conductive material, wherein said first and second dielectric layers are formed by one of the zirconium oxide and the hafnium oxide.

In the thin film capacitor according to the above-mentioned invention, said buffer layer is preferably formed by an amorphous material. Said buffer layer is preferably formed by a material selected from Al₂O₃, HfO₂, Ta₂O₅ and amorphous ZrO₂. Additionally, it is preferable that said first and second dielectric layers have the same thickness, and said buffer layer is thinner than said first and second dielectric layers Said first and second dielectric layers may be formed by a zirconium oxide, a thickness of each of said first and second dielectric layers may be 1 to 70 Å, and a thickness of said buffer layer is 1 to 20 Å. Said first dielectric layers, said buffer layer and said second dielectric layer may be formed in consecutive processes.

Additionally, there is provided according to another aspect of the present invention a thin film capacitor formed with a zirconium oxide or a hafnium oxide as a dielectric material, comprising: a lower electrode made of a conductive material; an upper electrode made of a conductive material; a plurality of dielectric layers formed between the lower electrode and the upper electrode; and a buffer layer made of an amorphous material formed between adjacent upper and lower layers among the plurality of dielectric layers, wherein said plurality of dielectric layers is formed by one of the zirconium oxide and the hafnium oxide.

In the above-mentioned thin film capacitor, said buffer layer is preferably formed by a material selected from Al₂O₃, HfO₂, Ta₂O₅ and amorphous ZrO₂.

Additionally, there is provided according to another aspect of the present invention a forming method of a thin film capacitor using a zirconium oxide or a hafnium oxide as a dielectric material, comprising: forming a lower electrode made of a conductive material; forming a first dielectric layer by one of the zirconium oxide and the hafnium oxide on the lower electrode; forming a buffer layer of a predetermined thickness on the first dielectric layer; forming a second dielectric layer of a predetermined thickness on the buffer layer by using a material the same as said first dielectric layer; and forming an upper electrode made of a conductive material on the second dielectric layer.

In the forming method of a thin film capacitor according to the above-mentioned invention, the formation of said first dielectric layer, the formation of said buffer layer and the formation of said second dielectric layer are preferably performed consecutively in a film deposition process according to an ALD method.

Additionally, there is provided according to another aspect of the present invention a computer readable storage medium storing a program causing a computer to perform a forming method of a thin film capacitor, comprising: forming a lower electrode made of a conductive material; forming a first dielectric layer by one of a zirconium oxide and a hafnium oxide on the lower electrode; forming a buffer layer of a predetermined thickness on the first dielectric layer; forming a second dielectric layer of a predetermined thickness on the buffer layer by using a material the same as said first dielectric layer; and forming an upper electrode made of a conductive material on the second dielectric layer.

In the computer readable storage medium according to the above-mentioned invention, said program preferably causes to perform the formation of said first dielectric layer, the formation of said buffer layer and the formation of said second dielectric layer consecutively in a film deposition process according to an ALD method.

Additionally, there is provided according to another aspect of the present invention a forming method of a thin film capacitor using a zirconium oxide or a hafnium oxide as a dielectric material comprising: forming a lower electrode made of a conductive material; forming a dielectric layer by one of a zirconium oxide and a hafnium oxide on the lower electrode; forming a buffer layer of a predetermined thickness on the dielectric layer; forming a multi-layer dielectric layer of a predetermined thickness by repeating the step of forming said dielectric layer and the step of forming said buffer layer for a predetermined number of times; and forming an upper electrode made of a conductive material on the multi-layer dielectric layer.

In the forming method of a thin film capacitor according to the above-mentioned invention it is preferable that the formation of said dielectric layer and the formation of said buffer layer are consecutively performed in a film deposition process according to an ALD method.

Additionally, there is provided according to another aspect of the present invention a computer readable storage medium storing a program for causing a computer to perform a forming method of a thin film capacitor, comprising: forming a lower electrode made of a conductive material; forming a dielectric layer by one of a zirconium oxide and a hafnium oxide on the lower electrode; forming a buffer layer of a predetermined thickness on the dielectric layer; forming a multi-layer dielectric layer of a predetermined thickness by repeating the step of forming said dielectric layer and the step of forming said buffer layer for a predetermined number of times; and forming an upper electrode made of a conductive material on the multi-layer dielectric layer.

In the computer readable storage medium according to the above-mentioned invention, said program preferable causes the formation of said dielectric layer and the formation of said buffer layer to be performed consecutively in a film deposition process according to an ALD method.

### Effect of the Invention

According to the present invention, the zirconium oxide layer or the hafnium oxide layer is divided into a plurality of layers so as to cause each layer to have a thickness smaller than a predetermined layer, and further a buffer layer is formed between the zirconium oxide layers or the hafnium oxide layers. Thereby, the surface roughness of the zirconium oxide layer or the hafnium oxide layer becomes small. As a result, an electric field concentration caused by the surface roughness becomes small and a leak current can be reduced.

### BRIEF DESCRIPTION OF DRAWINGS

FIG. 1 is a graph showing a relationship between a thickness and a surface roughness of a ZrO₂ film.

FIG. 2 is a view showing a device structure in which a thin film capacitor according to a first embodiment of the present invention is formed.

FIG. 3 is an illustration of a processing apparatus for performing a thin-film forming process according to an ALD method.

FIG. 4 is a flowchart f a thin-film capacitor producing process according to the first embodiment of the present invention.

FIG. 5 is a flowchart of a film deposition process when forming ZrO₂ layers shown in FIG. 2.

FIG. 6 is a flowchart of a film deposition process when forming an Al₂O₃ film as a buffer layer shown in FIG. 2.

FIG. 7 is a flowchart of a film deposition process when forming an HfO₂ film as a buffer layer shown in FIG. 2.

FIG. 8 is an outline structure diagram showing an example of a cluster tool for forming a thin film capacitor according to the present invention.

FIG. 9 is a graph showing a relationship between a thickness and a surface roughness of an HfO₂ film.

FIG. 10 is a view showing an example of a thin film capacitor of a multi-layer structure according to a second embodiment of the present invention.

FIG. 11 is a view showing an example of a thin film capacitor of a multi-layer structure according to the second embodiment of the present invention.

FIG. 12 is a view showing an example of a thin film capacitor of a multi-layer structure according to the second embodiment of the present invention.

FIG. 13 is a flowchart of a multi-layer structure thin-film capacitor producing process according to the second embodiment of the present invention.

FIG. 14 is a flowchart of a film deposition process when forming the HfO₂ layer shown in FIG. 10 through FIG. 12.

FIG. 15 is a flowchart of a film deposition process when forming the Al₂O₃ layer shown in FIG. 10 through FIG. 12.

FIG. 16 is a view showing a transistor structure in which a stacked layer film HfAlO according to the present invention is used for a gate electrode.

### DESCRIPTION OF REFERENCE NUMERALS

2 thin film capacitor
4 Si substrate
6 transistor structure
8 source area
10 drain area
12 gate electrode
14 wire contact
16 source electrode
22 lower electrode
24 upper electrode
26A, 26B ZrO₂ layer
28 buffer layer
36A HfO₂ layer
38 Al₂O₃ buffer layer
52 laminate layer (HfAlO)
54 gate electrode

### BEST MODE FOR CARRYING OUT THE INVENTION

Next, a description will be given, with reference to the drawings, of a thin film capacitor according to the first embodiment of the present invention.

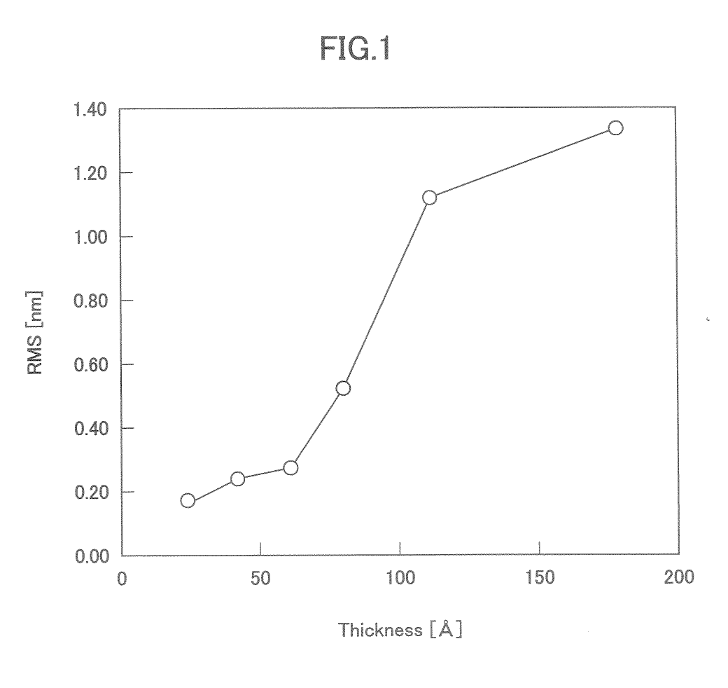

First, a description will be give of a surface roughness of a zirconium oxide film. FIG. 1 is a graph showing a relationship between a thickness and a surface roughness (surface mophorogy) of the zirconium oxide film (may be referred to as ZrO₂ film). It should be noted that the zirconium oxide contains oxides of zirconium other than ZrO₂.

The graph of FIG. 1 shows a relationship between the thickness and the surface roughness of the ZrO₂ film when the ZrO₂ film is produced on an Si substrate according to an ALD (Atomic Layer Deposition) method. As can be interpreted from FIG. 1, the surface roughness is equal to or smaller than 0.3 nm in RMS up to the thickness of the ZrO₂ by 60 Å, but the surface roughness turns to increase sharply when the thickness exceeds 60 Å.

Here, if, for example, the film thickness when forming a capacitor with a ZrO₂ film as a dielectric material is required to be equal to or larger than 60 Å if the dielectric constant of ZrO₂ ∈=21 to 30. For Example, if the thickness is 100 Å, the surface roughness increases and reaches close to 1.00 nm in RMS, which causes the surface of the ZrO₂ film to be a surface having convexoconcave into which an electric field concentrates. As a result, reliability of the thin film capacitor may be deteriorated. It is considered that the increase in the surface roughness of the ZrO₂ film depends on the crystallinity. That is, it is considered that, when forming a ZrO₂ film of a large thickness, a formation process time is long, and as the crystallization in the ZrO₂ film progresses and crystals grow, crystal grains near the surface grow and appear in convexoconcave. From this figure, a preferable capacitor film thickness is equal to or smaller than 70 Å and a roughness is equal to or smaller than 0.4 nm.

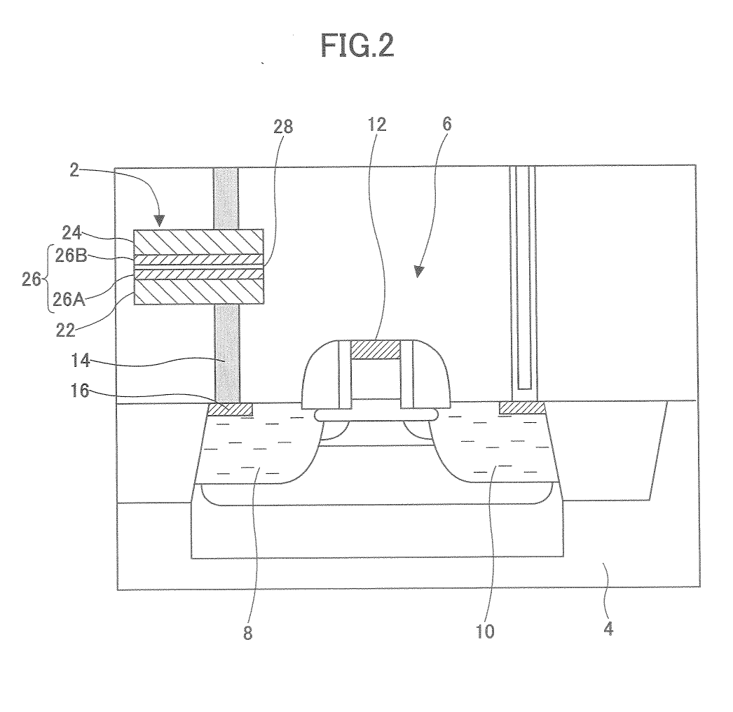

Thus, the present inventor devises to maintain the surface roughness small by sandwiching an amorphous layer between ZrO₂ films. FIG. 2 is an illustration of a device structure containing a thin film capacitor using a ZrO₂ film according to a first embodiment of the present invention.

The thin film capacitor 2 using the ZrO₂ film according to the first embodiment of the present invention is formed, for example, as a memory cell connected to a transistor structure 6 formed on a silicon substrate 4. The transistor structure 6 is a field effect transistor (FET) which has a source region 8, a drain region 10 and a gate electrode 12. The thin film capacitor 2 is connected to a source electrode 16 in the transistor structure 6 by a wiring contact 14 formed of tungsten (W) or the like.

The thin film capacitor 2 has a lower electrode 22 and an upper electrode 24 which are formed by an electrically conductive material such as, for example, TiN, and functions as a thin film capacitor by a ZrO₂ film 26 being formed therebetween as a dielectric layer having a high dielectric constant. The ZrO₂ thin film 26 is divided into a ZrO₂ layer 26A as a first dielectric layer on the lower electrode 22 side and a ZrO₂ layer 26B as a second dielectric layer on the upper electrode side, and is formed so that a buffer layer 28 is sandwiched between the ZrO₂ layer 26A and the ZrO₂ layer 26B.

Each of the ZrO₂ layers 26A and 26B is of a thickness of about 30 to 50 Å (3 to 5 nm), and the ZrO₂ layer 26A is in a good state in surface roughness. The buffer layer 28 is formed to be of a thickness of about 1 to 2 nm. Accordingly, the ZrO₂ layers 26A and 26B are laminated and the ZrO₂ thin film of a film thickness of about 60 to 100 Å is formed as a whole.

The buffer layer 28 is formed of an amorphous material such as Al₂O₃, HfO₂, Ta₂O₅, amorphous ZrO, etc., and preferably be a material of a high dielectric constant. The buffer layer 28 achieves a function of suppressing crystallization of the ZrO₂ layer 26B.

When forming the device structure shown in FIG. 2, the thin film capacitor 2 is formed after forming the transistor structure 6 with a multilayer structure. In the formation step of the thin film capacitor 2, the transistor structure 6 has already been formed, and in order to form the thin film capacitor 2 while maintaining the transistor structure 6, it is necessary to form a high dielectric constant film at a relatively low temperature. Thus, the ZrO₂ film, which has a high dielectric constant and is formable at a temperature condition of about 250° C., is used as a thin film capacitor.

The ZrO₂ thin film 26 is formed by an ALD method on the lower electrode 22 forced of, for example, TiN. Then, if the film thickness of the ZrO₂ thin film 26 is made to grow to 100 Å in a single thin-film-formation process, a surface roughness of the ZrO₂ thin film 26 becomes large as mentioned above, which results in an increase in a leak current due to an electric-filed concentration by the convexoconcave (convexoconcave of an interface between the ZrO₂ layer and the upper electrode 24) of the surface of the ZrO₂ film when a voltage is applied across the upper and lower electrodes 22 and 24, thereby decreasing the reliability of the capacitor.

Thus, in the present embodiment, the ZrO₂ thin film 26 is produced by separating into the ZrO₂ layers 26A and 26B and the film thickness of each of the ZrO₂ layers 26A and 26B is made to be 30 to 70 Å so that the ZrO₂ layer 26A is formed in a good state in the surface roughness, and crystallization of the ZrO₂ layer 26B is suppressed by forming the buffer layer 28 on the ZrO₂ layer 26A and forming the ZrO₂ layer 26B on the buffer layer 28, and, as a result, the surface roughness of the ZrO₂ layer 26B is suppressed to be small.

If the buffer layer 28 of an amorphous material is formed at a temperature equal to or lower than 250° C. after the lower ZrO₂ layer 26A is formed, the surface roughness of the ZrO₂ layer 26A is maintained at a small surface roughness at a time when the film thickness is 50 Å, and the surface of the buffer layer 28 turns to be a smooth surface. Accordingly, when forming the upper ZrO₂ layer 26B on the buffer layer 28, the ZrO₂ layer is formed on the surface of the buffer layer having a small roughness, and the surface roughness of the ZrO₂ layer 26B is substantially the same as that of the film thickness in the case where it is formed with a film thickness of 50 Å. That is, the surface roughness of the surface of each of the ZrO₂ layers 26A and 26B is equal to the surface roughness when forming it with a film thickness of 50 Å, which is a small roughness, and, thereby, a large electric-field concentration such as to increase a leak current does not occur.

It should be noted that an amorphous material in which crystal grains do not grow is suitable for a material of the buffer layer 28 for the sake of forming the upper ZrO₂ layer from a state where a roughness is small after resetting the surface state of the lower ZrO₂ layer 26A, and also a high dielectric material such as that functioning as a capacitor material is suitable. As such a material, there are Al₂O₃, HfO₂, Ta₂O₅, amorphous ZrO₂, etc.

As mentioned above, according to the present embodiment, the surface roughness is reduced by forming the buffer layer 28 of an amorphous material between the two ZrO₂ layers 26A and 26B so as to suppress an electric-field concentration on the surface of the ZrO₂ layer, which enables formation of the thin film capacitor in which a leak current is reduced.

Next, a description will be given of a process of producing the thin-film capacitor 2.

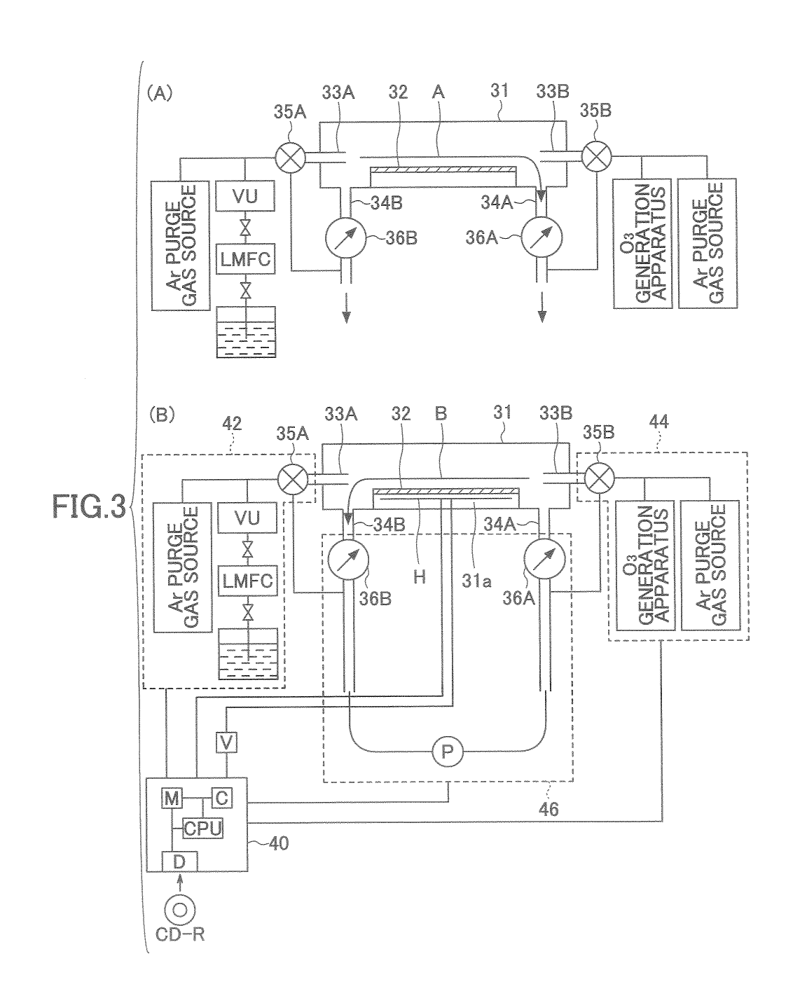

The above-mentioned ZrO₂ layers 26A and 26B and the buffer layer 28 can be formed by an ALD method. FIG. 3 is an illustration showing an example of a processing apparatus for forming a thin film by an ALD method, (A) showing a state where a source gas is being supplied, (B) showing a state where an oxidation gas is being supplied. It should be noted that although a control system for controlling an operation of the processing apparatus is shown in FIG. 3(B), the illustration is omitted in FIG. 3(A).

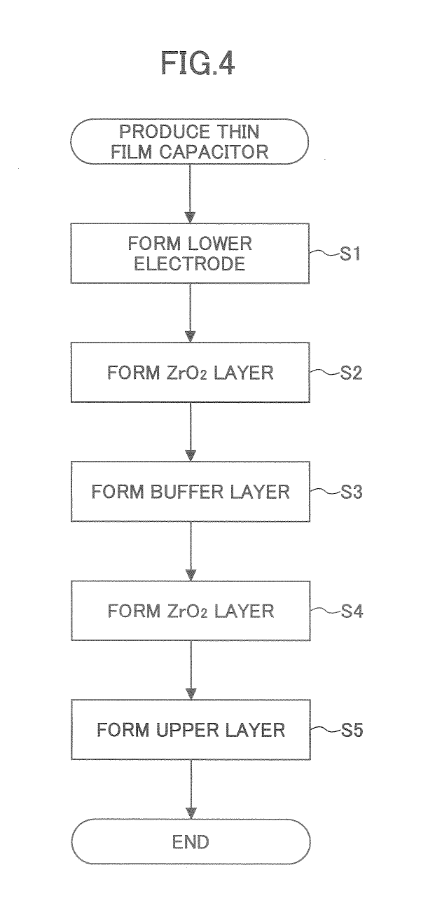

In a producing process of a thin film capacitor, as shown in a flowchart of FIG. 4, first, the lower electrode 22 is formed on a substrate (step S1), the ZrO₂ layer 26A is formed on the lower electrode 22 by an ALD method (step S2) a buffer layer 28 is formed thereon (step S3), subsequently the ZrO₂ layer 26B is formed (step S4), and the upper electrode 24 is formed thereon (step S5). The series of processes from steps S1 to S5 can be performed by the processing apparatus such as shown in FIG. 3 or a cluster tool mentioned below. Alternatively, the process of steps S3 to S5 may be performed consecutively by a single processing apparatus or a cluster tool.

In the processing apparatus shown in FIG. 3, a first process gas supply port 33A is provided to a process container 31, in which a substrate 32 that is an object to be processed is retained, on a first side with respect to the substrate 32, and a first exhaust port 34A is provided on a side opposite to the first side. Further, the process container 31 is provided with a second process gas supply port 33B on a second side, and provided with a second exhaust port 34B on the first side. A first process gas A is supplied to the first process gas supply port 33A via a first raw material switch valve 35A, and a second process gas B is supplied to the second process gas supply port 33B via a second raw material switch valve 35B. Further, the first exhaust port 34A is evacuated through a first exhaust amount adjust valve 36A, and the second exhaust port 34B is evacuated through a second exhaust amount adjust valve 36B.

A liquid raw material source (for example, TEMAZ) is supplied to a vaporizer (VU) together with an inert gas such as argon or the like while being controlled in a flow amount by a liquid mass-flow controller (LMFC) on the side of the first process gas supply port 33A, and is vaporized and turned to be a gas and supplied to the first process gas supply port 33A via a switch valve 35A.

On the other hand, O₃ generated by an O₃ generation apparatus is supplied to the second process gas supply port 33B through a switch valve 35B together with an inert gas such as argon or the like on the side of the second process gas supply port. Additionally, argon gas as a purge gas is supplied from an Ar purge gas source to the second process gas supply port 33B through the switch valve 35B.

It should be noted that the switch valve 35A is connected to a downstream side of the second exhaust amount adjust valve 36B by a vent. Additionally, the switch valve 35B is connected to a downstream side of the first exhaust amount adjust valve 36A by a vent.

Moreover, the substrate 32 is placed on a placement stage 31a, and is heated by a heater H that is a heat source incorporated in the placement stage 31a. Although the heater H is a heater for resistance heating, a lamp may be used as the heating source.

First, the first process gas A (high dielectric material organic metal compound) is supplied to the first process gas supply port 33A through the first raw material switch valve 35A in the process of FIG. 3(A) so as to cause the first process gas A to be adsorbed onto a substrate surface in the process container 31. At that time, the first process gas flows in a first direction along the substrate surface from the first process gas supply port 33A to the first exhaust port 34A by driving the first exhaust port 34A opposite to the first process gas supply port 33A.

Next, a second process gas B (oxidizer) is supplied to the second process gas supply port 33B through the second raw material switch valve 35B in the process of FIG. 3(B) so as to cause the second process gas B to flow along the surface of the substrate 32 in the process container 31. As a result, the second process gas B acts (oxidation action) on the first process gas molecules previously adsorbed onto the substrate surface, and a high dielectric material molecule layer (high dielectric material metal oxide) is formed on the substrate surface. At that time, the second process gas flows in a second direction along the substrate surface from the second process gas supply port 33B to the second exhaust port 34B by driving the second exhaust port 34B opposite to the second process gas supply port 33B.

By repeating the processes of FIG. 3(A) and FIG. 3(B), a desired high dielectric material film is formed on the substrate 32. Although the supply of the second process gas B from the second raw material switch valve 35B to the second process gas supply port 33B is interrupted in the process of FIG. 3(A) and the supply of the first process gas A from the first raw material switch valve 35A to the first process gas supply port 33A is interrupted in the process of FIG. 3(B), it is preferable to perform a purge by supplying an inert gas from the second raw material switch valve 35B to the second process gas supply port 33B in the process of FIG. 3(A) in order to avoid occurrence of separation due to the first process gas A introduced from the first process gas supply port 33A in the process of FIG. 3(A) entering the opposite second process gas supply port 33B. Similarly, it is preferable to perform a purge by supplying an inert gas from the first raw material switch valve 35A to the first process gas supply port 33A in the process of FIG. 3(B). Further, although the first exhaust amount adjust valve 36A is set to be a large valve opening degree so as to exhaust the first process gas that has passed through the surface of the substrate 32 in the process of FIG. 3(A), it is preferable, in consideration of a valve opening and closing operation at a high temperature, that the second exhaust amount adjust valve 36B is not closed completely but set to a small valve opening degree equal to or less than 3%, for example. Similarly, although the second exhaust amount adjust valve 36B is set to be a large valve opening degree in the process of FIG. 3(B), it is preferable that the first exhaust amount adjust valve 36A is also not closed completely but set to a small valve opening degree equal to or less than 3%, for example.

The process container 31 is formed in a flat shape so that the first and second process gases flow in a flow along the sheet shaped object to be processed on the surface of the substrate 32, and also the first and second process gas supply ports 33A and 33B are formed with corresponding flat, slit-like opening parts. Further, the first and second exhaust ports 34A and 34B are also formed in a slit-shape that extend in a direction substantially perpendicular to the flow direction of the first or second process gas. Additionally, exhaust is performed downward and evenly from the slits perpendicular to the flow direction of the process gases, and, thereby, the sheet-like process gas flow is not disturbed.

It should be noted that the operation of the processing apparatus is controlled by a control unit 40 as shown in FIG. 3(B). Specifically, the control unit 40 controls a power supply to a heater 38 provided to a susceptor 37 on which the substrate 32 is placed so as to control a process temperature of the substrate 32. Additionally, the control unit 40 controls gas supply systems 42 and 44 and an exhaust system 46 so as to control a flow of the process gases in the process container 31 as mentioned above.

In order to perform the above-mentioned control, the control unit 40 comprises a central processing unit (CPU), a memory (M) for storing data and programs, a peripheral circuit (C), etc., and can be constructed by, for example, a general purpose computer. By the control unit 40 operating the processing apparatus in accordance with predetermined programs, the above-mentioned thin film capacitor producing process is performed to form a thin film capacitor. The program for the thin film capacitor producing process may be stored in the memory (M) in the control unit 40 or stored in a computer readable storage medium such as, for example, a CD-ROM, a flexible magnetic disk, or a magneto-optical disk so as to be read by a drive apparatus (D) provided to the control unit 40.

In the above-mentioned processing apparatus, the ZrO₂ layers can be formed on the substrate by using a raw material containing Zr as the first process gas and using an oxidation gas containing O₃ as the second process gas. Additionally, by switching the first process gas to a high dielectric material organic metal compound containing Al or Hf, a high dielectric material metal oxide layer such as an Al₂O₃ layer, an HfO₂ layer or the like can be formed as the buffer layer.

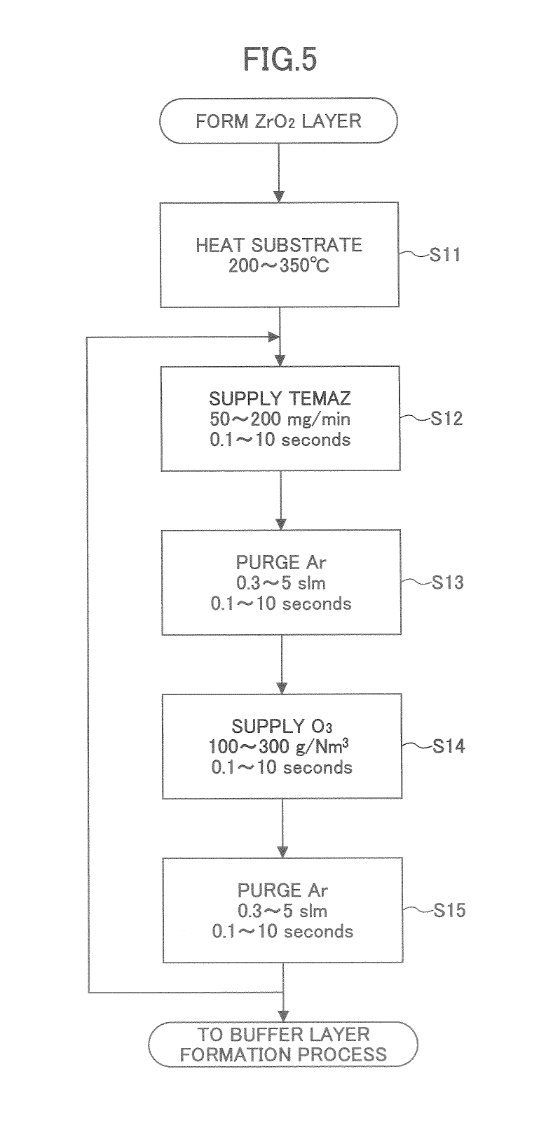

First, as shown in FIG. 5, the substrate in which the transistor structure 6 and the lower electrode 22 are formed is placed in the process container 31, and the substrate is heated at 200 to 350° C. (step S11). Next, the first raw material switch valve 35A is opened so as to introduce an organic zirconium compound, such as tetrakis ethyl methyl amino zirconium (TEMAZ) containing organic zirconium, as the first process gas A into the process container 31. A raw material used for depositing ZrO₂, a zirconium amino base or zirconium alkoxide may be used other than TEMAZ. At this time, the second raw material switch valve 35B is closed, and set to be in the state shown in FIG. 3(A). Accordingly, the TEMAZ flows on the substrate, and the TEMAZ is thermally decomposed, which removes organic materials such as an alkyl base, and Zr is adsorbed onto the substrate (lower electrode 22) (step S12). At this time, it is preferable that a flow rate of the TEMAZ is adjusted to 50 to 200 mg/min and a time to supply the TEMAZ is set to 0.1 to 10 seconds. In addition to the TEMAZ, a raw material containing organic Zr of alkoxide base or tetrakis base such as tetrakis dimethyl zirconium, tetratertial butoxide zirconium, etc., may be used.

After the supply of the TEMAZ is completed in step S12, a process of purging the TEMAZ in the process container 31 is performed subsequently (step S13). In this Process, in order to eliminate the TEMAZ, Ar is supplied to the process container 31 as an inert gas, and is exhausted from the exhaust ports 34A and 34B. It is preferable that the flow rate of Ar is 0.3 to 5 slm and a purge time is 0.1 to 10 seconds. Thereby, a film thickness can be controlled with good accuracy.

After the purge by Ar is completed, the second raw material switch valve 35B is then opened so as to introduce O₃ as the second process gas B into the process container 31. At this time, the first raw material switch valve 35A is closed and is set to be in the state shown in FIG. 3(B). Accordingly, O₃ flows on the substrate and Zr adsorbed onto the substrate and O₃ react with each other, which produces ZrO₂ on the substrate (step S14). At this time, it is preferable that the flow rate of O₃ is adjusted to 100 to 300 g/Nm³ and the time of supplying O₃ is set to 0.1 to 10 seconds.

After the supply of O₃ is completed in step S14, a process of purging and removing O₃ and reaction byproducts in the process container is performed (step S15). In this process, Ar is supplied to the process container 31 as an inactive gas and is exhausted from the exhaust ports 34A and 34B. It is preferable that the flow rate of Ar is 0.3 to 5 slm and the purge time is 0.1 to 10 seconds.

The above-mentioned process is repeated until the thickness of the ZrO₂ layer on the substrate reaches about 50 Å. Since the thickness of the ZrO₂ layer produced by one cycle of the above-mentioned steps S11 to S15 is about 1 Å, the above-mentioned process is repeated for 50 times so as to form the ZrO₂ layer of a thickness of 50 Å. This ZrO₂ layer corresponds to the ZrO₂ layer 26A in FIG. 2.

After the ZrO₂ layer 26A of the thickness of 50 Å is formed then, it proceeds to a formation process of the buffer layer 28. In the formation process of the buffer layer 28, an amorphous state Al₂O₃ layer (∈=9) or an HfO₂ layer (∈=20 to 30) is formed as the buffer layer by an ALD method on the previously formed ZrO₂ layer in the same manner.

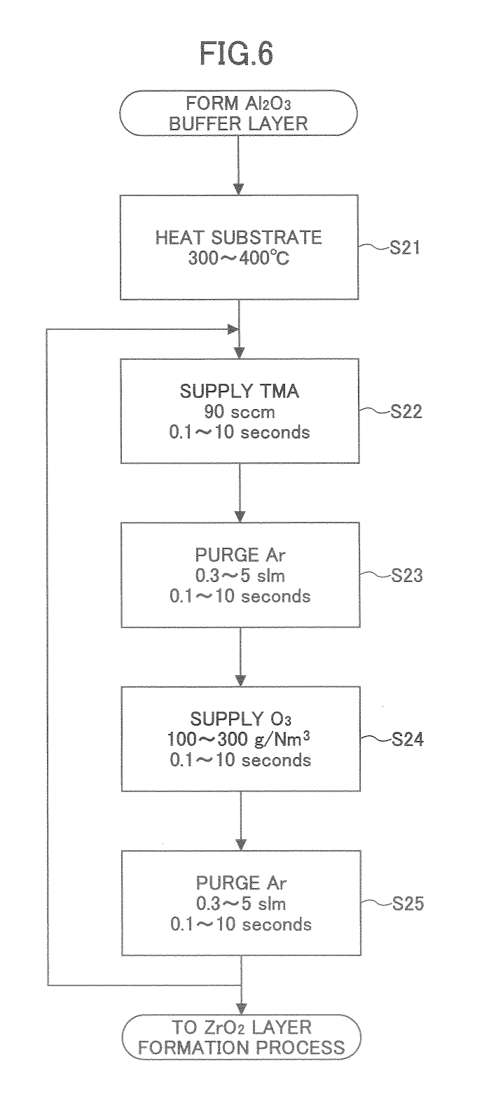

A description will be give, with reference to FIG. 6, of a process in a case where an Al₂O₃ layer, for example, is formed as a buffer layer.

First, the substrate in the process container 31 is heated at 300 to 400° C. (step S21). Next, the first raw material switch valve 35A is opened so as to supply, for example, trimethyl aluminum (TMA) containing Al as the first process gas to the process container 31. At this time, the second raw material switch valve 35B is closed, and set to be in the state shown in FIG. 3(A). Accordingly, the TMA flows on the substrate, and Al is adsorbed onto the substrate (ZrO₂ layer) (step S22). At this time, it is preferable that a flow rate of the TMA is adjusted to 90 sccm and a time to supply the TMA is set to 0.1 to 10 seconds. Other than the TMA, a raw material containing organic Al may be used as the first process gas A.

After the supply of the TMA is completed in step S22, a process of purging the TMA in the process container 31 is performed subsequently (step S23). In this process, Ar is supplied to the process container 31 as an inert gas, and is exhausted from the exhaust ports 34A and 34B. It is preferable that the flow rate of Ar is 0.3 to 5 slm and a purge time is 0.1 to 10 seconds.

After the purge by Ar is completed, the second raw material switch valve 35B is then opened so as to introduce O₃ as the second process gas B Into the process container 31. At this time, the first raw material switch valve 35A is closed and is set to be in the state shown in FIG. 3(B). Accordingly, O₃ flows on the substrate and Al adsorbed onto the substrate and O₃ react with each other, which produces Al₂O₃ on the substrate (step S24). At this time, it is preferable that the flow rate of O₃ is adjusted to 100 to 300 g/Nm³ and the time of supplying O₃ is set to 0.1 to 10 seconds. An active radical such as oxygen radical may be used instead of O₃.

After the supply of O₃ is completed in step S24, a process of purging and removing O₃ and reaction byproducts in the process container 31 is performed (step S25). In this process, Ar is supplied to the process container 31 as an inactive gas and is exhausted from the exhaust ports 34A and 34B. It is preferable that the flow rate of Ar is 0.3 to 5 slm and the purge time is 0.1 to 10 seconds.

The above-mentioned process is repeated until the thickness of the Al₂O₃ buffer layer on the substrate reaches about 10 Å. Since the thickness of the Al₂O₃ layer produced by one cycle of the above-mentioned steps S21 to S25 is about 1 Å, the above-mentioned process is repeated for 10 times so as to form the Al₂O₃ layer of a thickness of 10 Å. This Al₂O₃ layer corresponds to the buffer layer 28 in FIG. 2. The preferable thickness is 1 to 20 Å, and more preferably the film thickness is 1 to 10 Å in consideration of the dielectric constant ∈=9 of Al₂O₃.

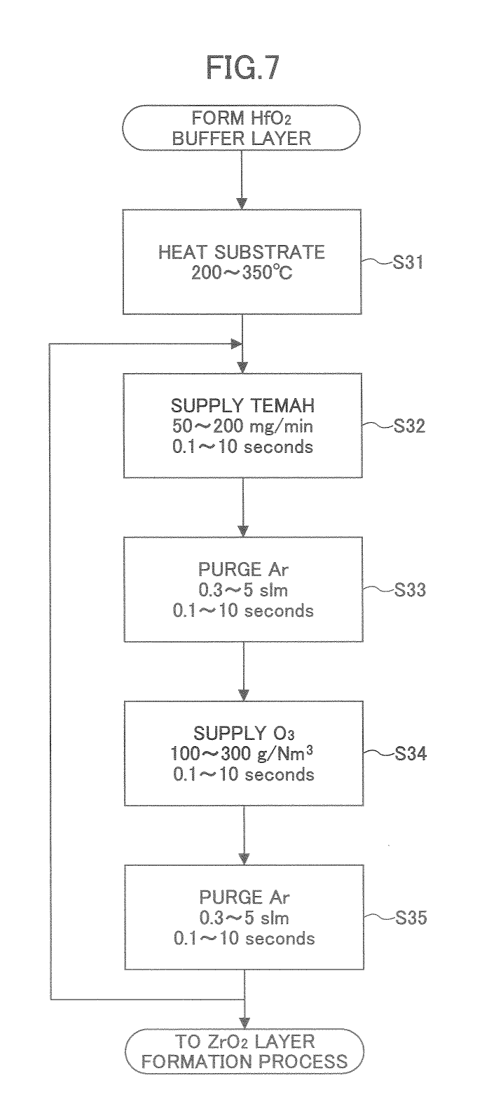

Additionally, a description will be given, with reference to FIG. 7, of a process in a case where an HfO₂ layer is formed as a buffer layer.

First, the substrate in the process container 31 is heated at 200 to 350° C. (step S31) Next, the first raw material switch valve 35A is opened so as to supply, for example, triethylmethyl amino hafnium (TEMAH) as the first process gas A to the process container 31. At this time, the second raw material switch valve 35B is closed, and set to be in the state shown in FIG. 3(A). Accordingly, the TEMAH flows on the substrate, and the TEMAH is thermally decomposed, which removes organic materials such as an alkyl base, and Hf is adsorbed onto the substrate (on the ZrO₂ layer) (step S32). At this time, it is preferable that a flow rate of the TEMAH is adjusted to 50 to 200 mg/min and a time to supply the TEMAH is set to 0.1 to 10 seconds. Other that the TEMAH a raw material containing organic Hf of alkoxide base or tetrakis base such as tetrakis dimethyl hafnium, tetratertial butoxide hafnium, etc., may be used as the first process gas.

After the supply of the TEMAH is completed in step S32, a process of purging the TEMAH in the process container 31 is performed subsequently (step S33). In this process, Ar is supplied to the process container 31 as an inert gas, and is exhausted from the exhaust ports 34A and 34B. It is preferable that the flow rate of Ar is 0.3 to 5 slm and a purge time is 0.1 to 10 seconds.

After the purge by Ar is completed, the second raw material switch valve 35B is then opened so as to introduce O₃ as the second process gas B into the process container 31. At this times the first raw material switch valve 35A is closed and is set to be in the state shown in FIG. 3(B). Accordingly, O₃ flows on the substrate and Hf adsorbed onto the substrate and O₃ react with each other, which produces HfO₂ on the substrate (step S34). At this time, it is preferable that the flow rate of O₃ is adjusted to 100 to 300 g/Nm³ and the time of supplying O₃ is set to 0.1 to 10 seconds.

After the supply of O₃ is completed in step S34, a process of purging O₃ and reaction byproducts in the process container 31 is performed (step S35). In this process, Ar is supplied to the process container 31 as an inactive gas and is exhausted from the exhaust ports 34A and 34B. It is preferable that the flow rate of Ar is 0.3 to 5 slm and the purge time is 0.1 to 10 seconds.

The above-mentioned process is repeated until the thickness of the HfO₂ layer on the substrate reaches about 10 Å. Since the thickness of the HfO₂ layer produced by one cycle of the above-mentioned steps S31 to S35 is about 1 Å, the above-mentioned process is repeated for 10 times so as to form the HfO₂ layer of a thickness of 10 Å. This HfO₂ layer corresponds to the buffer layer 28 in FIG. 2. The preferable film thickness is 1 to 70 Å, and more preferably the film thickness is 1 to 10 Å.

As mentioned above, after the formation of the buffer layer 28 on the ZrO₂ layer 26A is completed, the cycle of steps S11 to S15 shown in FIG. 5 is repeated again so as to form a ZrO₂ layer of a thickness of about 50 A on the buffer layer 28. This ZrO₂ layer formed on the buffer layer 28 corresponds to the ZrO₂ layer 26B shown in FIG. 2.

After the formation of the ZrO₂ layer 26B is completed, the upper electrode 24 is formed on the ZrO₂ layer 26B, and the thin film capacitor 2 is completed. It should be noted that the lower electrode 22 and the upper electrode 24 are not limited to a TiN film, and they may be formed by various conductive materials. For example, as for the lower electrode, PolySi, Ru, etc., may be used.

Moreover, although the formation process of the above-mentioned ZrO₂ layer and the formation process of the buffer layer are performed according to a film-deposition process using an ALD method, they may be performed according to a film-deposition process using a CVD method other than the ALD method.

Moreover, although the thin film capacitor comprising two ZrO₂ layers and the buffer layer provided therebetween was explained in the above-mentioned embodiment, the present invention is not limited to two ZrO₂ layers, and the thin film capacitor having a plurality of ZrO₂ layers, three or more, may be made. That is, a plurality of ZrO₂ layers are formed between the lower electrode and the upper electrode, and a buffer layer made of an amorphous material may be formed between adjacent upper and lower layers from among the plurality of ZrO₂ layers.

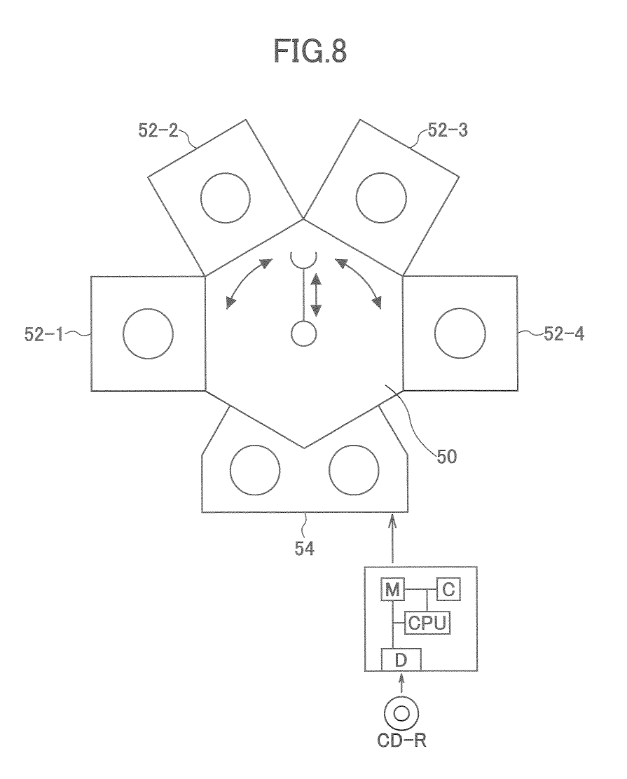

As a processing apparatus for forming the above-mentioned zirconium oxide thin film capacitor 2, a cluster tool such as shown in FIG. 8 can be used. The cluster tool shown in FIG. 8 is constituted by arranging four process chambers 52-1 to 52-4 and a load lock chamber around a vacuum conveyance chamber having a conveyance arm. For Example, it is assumed that the process chambers 52-1 to 52-3 are chambers for forming the ZrO2 layers 26A and 26B on a substrate and the process chamber 52-4 is a chamber for forming the buffer layer 28.

The operation of the cluster tool is controlled by a control part 55 constituted by a general purpose computer, etc. The control part 55 comprises a central processing unit (CPU), a memory (M) for storing data and programs, a peripheral circuit (C), a drive apparatus (D) for reading a recording medium, etc. The control part 55 causes each device of the cluster tool in accordance with a predetermined program so as to have the above-mentioned thin film capacitor producing process, thereby forming the thin film capacitor. The program for producing a thin film capacitor may be stored in the memory (M) in the control part 55, or stored in a computer readable storage medium such as, for example, a CD-ROM, a flexible magnetic disk, a magneto-optical disk, etc., so as to be read by the drive apparatus (D) provided in the control part 55.

It should be noted that the arrangement and the number of chambers are not limited to that shown in FIG. 8, and can be arbitrarily selected if needed.

Next, a description will be given of a series of formation processes of the thin film capacitor.

A ZrO₂ layer is deposited on a substrate by the ZrO₂ film deposition chamber 52-1, and, after completion, the substrate is conveyed into the buffer layer chamber 52-4 so as to form an Al₂O₃ buffer layer. Then, the substrate is conveyed into the ZrO₂ film deposition chamber 52-1 again so as to form a ZrO₂ layer on the buffer layer, and, thereby, a thin-film capacitor is formed. After completion, the substrate is taken out of the ZrO₂ film deposition chamber 52-1 by the conveyance arm and is returned to a cassette (not shown in the figure) through the load lock chamber 54. Similarly, thin film capacitors are formed on substrates by using the ZrO₂ film deposition chambers 52-2 and 52-3.

Although the ZrO₂ layer requires a relatively long process time since it is formed by an ALD method, the buffer layer requires a process time shorter than the ZrO₂ layer since the film thickness is small. Thus, in order to equalize the time for the series of processes, three process chambers 52-1 to 52-1 are assigned to the film deposition process of the ZrO₂ layer and one process chamber 52-1 is assigned to the film deposition process of the buffer layer. Thereby, the series of processes for forming the thin film capacitor according to the present invention, which processes are for forming the ZrO₂ layer 26A, forming the buffer layer 28 thereon, and forming the ZrO₂ layer 26B thereon, can be efficiently performed.

It should be noted that the structure of the cluster tool and the process sequence are not limited to those, and various structures may be considered other than the structure shown in the figure.

As mentioned above, although the ZrO₂ layer is used as a dielectric layer in the first embodiment of the present invention, the same effect can be obtained in a case where an HfO₂ layer having a high dielectric constant as well as the ZrO₂ layer is used as a dielectric layer.

Next, a description will be given of a thin film capacitor according to a second embodiment of the present invention.

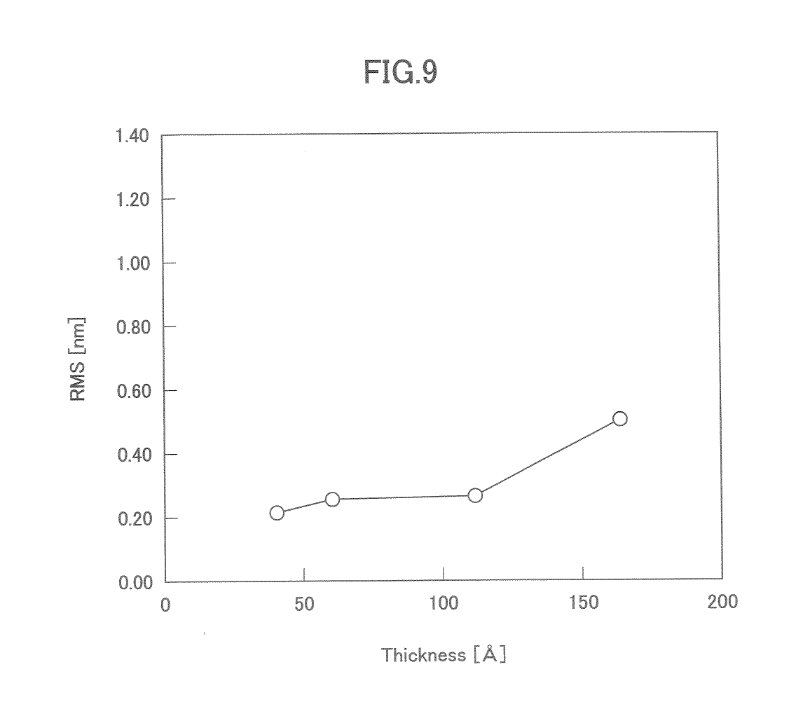

First, a surface roughness of a hafnium oxide film will be explained. FIG. 9 is a graph showing a relationship between a thickness and a surface roughness (surface mophorogy) of a hafnium oxide film (may be referred to as HfO₂ film).

The graph of FIG. 9 shows a relationship between a thickness and a surface roughness of an HfO₂ film when the HfO₂ film is produced on an Si substrate by an ALD method. It can be appreciated from FIG. 9 that if the thickness of the HfO₂ film increases, the surface roughness also increases.

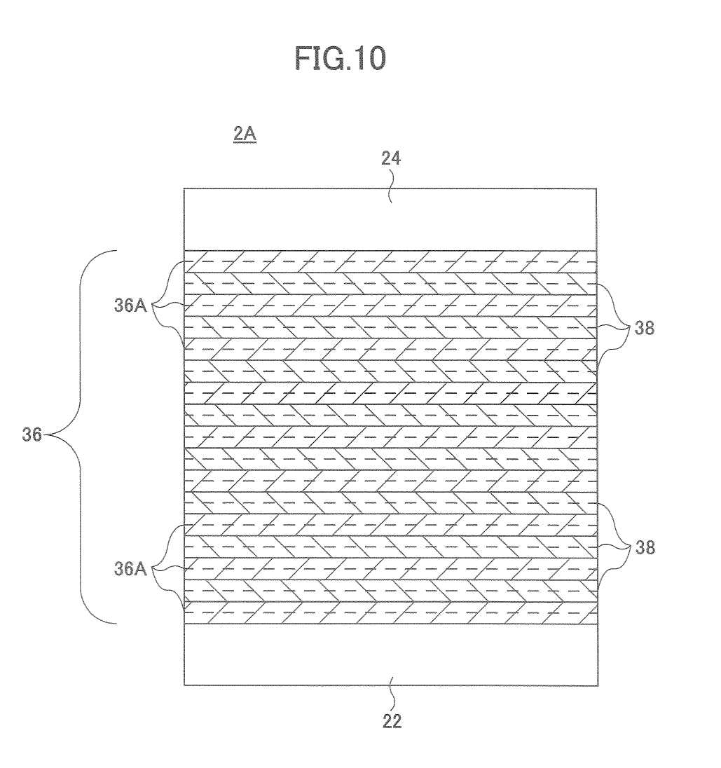

Thus, the present inventor considered to maintain the surface roughness to be small by sandwiching an amorphous layer in the ZrO₂ film or the HfO₂ film. FIG. 10 is an illustration showing a structure of a thin film capacitor using an HfO₂ film according to the second embodiment of the present invention. It should be noted that the thin film capacitor 2A using the HfO₂ film according to the second embodiment of the present invention. It should be noted that, similar to the thin film capacitor using the ZrO₂ film according to the above-mentioned first embodiment, the thin film capacitor 2A using the HfO₂ film according to the second embodiment of the present invention is formed as a memory cell connected to a transistor structure formed on a silicon substrate, for example, as shown in FIG. 2.

The thin film capacitor 2A has the lower electrode 22 and the upper electrode 24 which are formed by a conductive material such as, for example, TiN, and an HfO₂ thin film 36 as a dielectric layer having a high dielectric constant is formed between those, thereby functioning as a thin film capacitor. The HfO₂ thin film is divided into a plurality of HfO₂ layers 36A as a dielectric layer, and has a multi-layer structure in which the buffer layer 38 is sandwiched between adjacent upper and lower HfO₂ layer 36A.

The buffer layer 38 can be formed by an amorphous material such as Al₂O₃, Ta₂O₅, amorphous ZrO₂, etc. In the present embodiment, Al₂O₃ is used as a material for forming the buffer layer 38. The buffer layer 38 achieves a function of suppressing crystallization of the HfO₂ layer 36A. That is, a temperature of crystallization of HfO₂ can be raised.

The thin film capacitor using the HfO₂ film shown in FIG. 10 is formed by forming each layer of the plurality of HfO₂ layers 26A and each layer of the plurality of Al₂O₃ buffer layers by an ALD method. Although the ratio of the thickness of the HfO₂ layer to the thickness of the Al₂O₃ buffer layer 38 is 1:1 in FIG. 10, actually, the HfO₂ layer 36A is formed by the ALD method corresponding to two cycles, the Al₂O₃ buffer layer 38 is formed by the ALD method corresponding to two cycles, and repeating those so as to be the HfO₂ film of a predetermined thickness.

Since the thickness (about 1 Å) of the HfO₂ layer formed by one cycle of the ALD method is nearly equal to the thickness (about 1 Å) of the Al₂O₃ layer formed by one cycle of the ALD method, the ratio of the thickness of the HfO₂ layer 36A to the thickness of the HfO₂ layer 38 is 1:1 in FIG. 10. In FIG. 10, dashed lines drawn in each layer of the HfO₂ layers 28A and each layer of the Al₂O₃ buffer layers 38 indicate a thickness of a layer formed by one cycle of ALD method. That is, it can be appreciated that the multi-layer structure shown in FIG. 10 is made by forming the HfO₂ layer 26A by two cycles of the ALD method and forming the Al₂O₃ buffer layer 38 thereon by two cycles of the ALD method, and repeating those to make the multi-layer structure. It should be noted that the number of repetitions is not that shown in FIG. 10, and if an HfO₂ film of a thickness of, for example, about 10 μm (100 Å) is to be formed practically, repetition will be made 49 times.

It should be noted that, in the following explanation, the ratio of the thickness of the HfO₂ layer 36A to the thickness of the Al₂O₃ buffer layer 38 is represented by a ratio (m:n) of cycle numbers of the ALD method. For example, in the structure shown in FIG. 10, since the HfO₂ layer 36A is formed by m=2 cycles of the ALD method and the Al₂O₃ buffer layer 39 is formed by n=2 cycles of the ALD method, it is represented by the ratio of the thicknesses m:n=2:2.

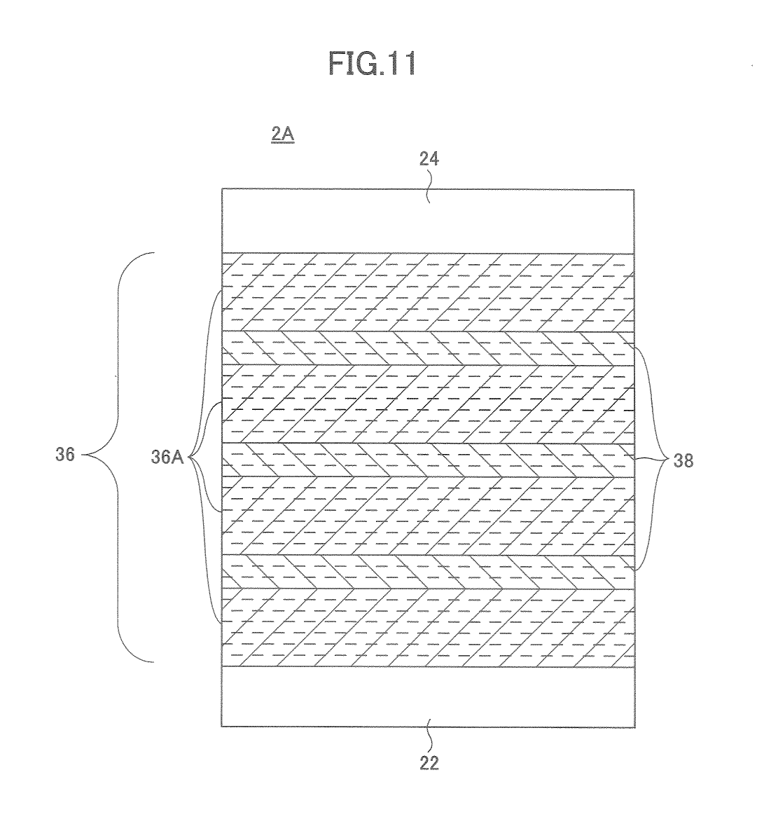

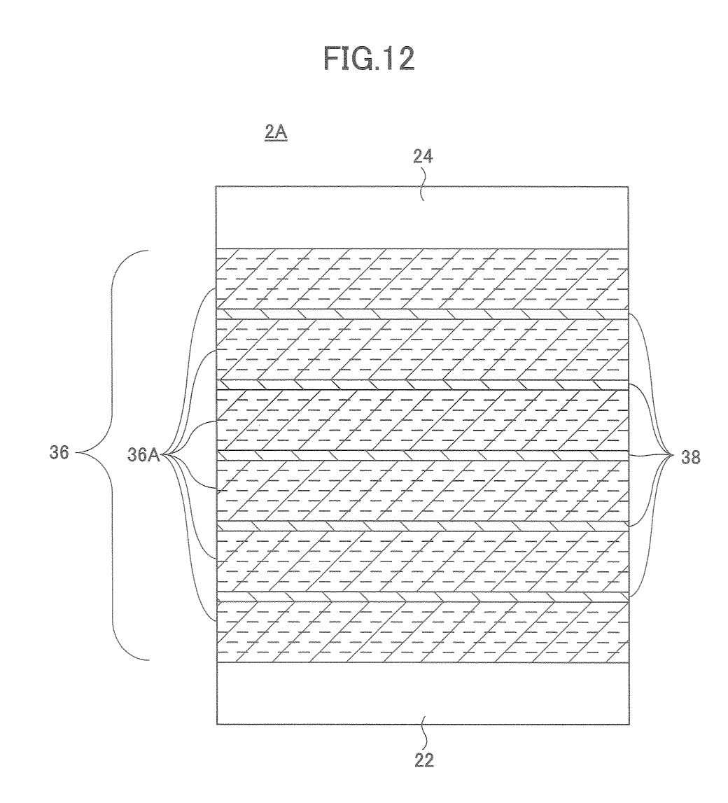

The ratio of the thickness of the HfO₂ layer 36A and the thickness of the Al₂O₃ buffer layer 38 is not limited to 2:2, and it can be arbitrarily changed depending on a characteristic required for a thin film capacitor to be formed. A thin film capacitor shown in FIG. 11 is formed with the ratio of the thickness of the HfO₂ layer 36A to the thickness of the Al₂O₃ buffer layer 38 being set to 7:3. Additionally, a thin film capacitor shown in FIG. 12 is formed with the ratio of the thickness of the HfO₂ layer 36A to the thickness of the Al₂O₃ buffer layer 38 being set to 5:1.

Shown below are results of measurements of surface roughness RMS of HfO₂ thin film capacitors having the structures shown in FIG. 10 through FIG. 12 that were formed so as to have a thickness of about 90 Å.

| Hf:Al | thickness (Å) | RMS (mm) |
|---|---|---|
| 5:1 | 90 | 0.184 |
| 7:3 | 84 | 0.225 |
| 2:2 | 90 | 0.194 |

It was appreciated from the above-mentioned results of measurements that the RMS values can sufficiently suppress the leak current even when the ratio of the thickness of the HfO₂ layer and the thickness of the Al₂O₃ buffer layer 38 is varied. The multi-layer structures shown in FIG. 10 through FIG. 12 are applicable to the ZrO₂ thin film capacitor explained in the above-mentioned first embodiment. Shown below are results of measurements of surface roughness RMS of ZrO₂ thin film capacitors having the structures shown in FIG. 10 through FIG. 12 that were formed so as to have a thickness of about 90 Å.

| Zr:Al | thickness (Å) | RMS (mm) |
|---|---|---|
| 5:1 | 95 | 0.36 |
| 7:3 | 93 | 0.32 |
| 2:2 | 96 | 0.34 |

It was appreciated from the above-mentioned results of measurements that the RMS values can sufficiently suppress the leak current even when the ratio of the thickness of the HfO₂ layer and the thickness of the Al₂O₃ buffer layer 38 is varied.

As mentioned above, according to the present embodiment, by forming a plurality of HfO₂ layers 36A and the buffer layers 28 of an amorphous material, a thin film capacitor in which the surface roughness is reduced so as to suppress an electric field concentration in the surface of the HfO₂ layer can be obtained. Additionally, the same effect can be obtained by using a ZrO₂ layer instead of the HfO₂ layer.

Next a description will be given of a process of producing the thin film capacitor 2A of the above-mentioned multi-layer structure with an HfO₂ thin film capacitor as an example.

The above-mentioned HfO₂ layers 36A and buffer layers 38 can be formed by an ALD method. A processing apparatus for forming a thin film by an ALD method is the same as the processing apparatus explained in the above-mentioned first embodiment with reference to FIG. 3, and a description thereof will be omitted.

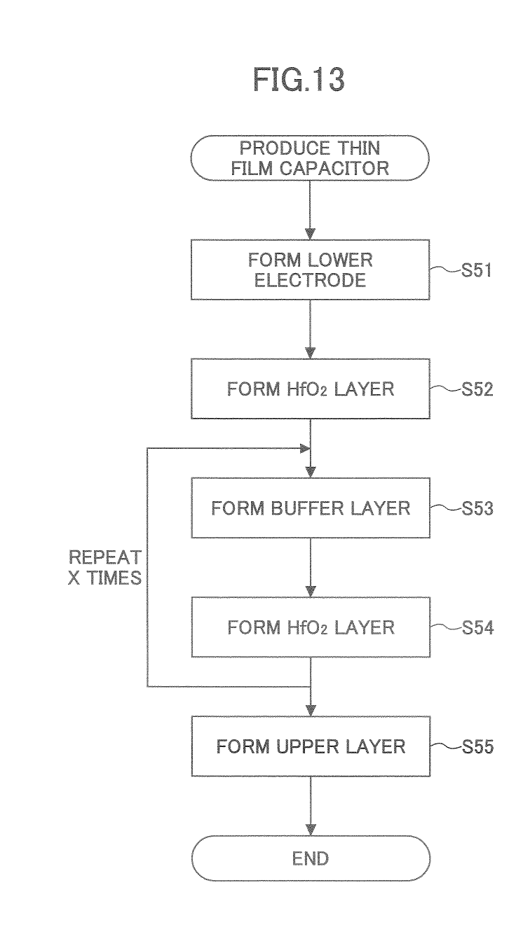

In the producing process of the HfO₂ thin film capacitor of a multi-layer structure, first as shown in the flowchart of FIG. 13, forming the lower electrode 22 on a substrate (step S51), forming the HfO₂ layer 36A on the lower electrode 22 by an ALD method (step S52), forming the buffer layer 38 thereon (step S53), and subsequently, forming the HfO₂ layer 36A (step S54). Here, the process returns to step S53 and after repeating the process of the step S53 and the step S54, forming the upper electrode 24 on the last formed HfO₂ layer (step S55). Here the number of times X of repetition is a value that is set so that the thickness of the formed HfO₂ layers 36A and the thickness of the buffer layers 38 become a predetermined thickness.

The series of processes from the step S51 to S55 can be performed consecutively by the processing apparatus such as shown in FIG. 3 or the cluster tool such as shown in FIG. 8. Or, the process of steps S52 to S54 may be performed by a cluster tool provided with one processing apparatus or a plurality of apparatuses by each apparatus consecutively.

In the processing apparatus shown in FIG. 3, the HfO₂ layer can be formed on a substrate by using a raw material containing Hf as the first process gas and using an oxidation gas containing O₃ as the second processing gas. Additionally, the Al₂O₃ can be formed as the buffer layer by switching the first gas to a raw material containing Al. The stacked film constitutes HfAlO composition.

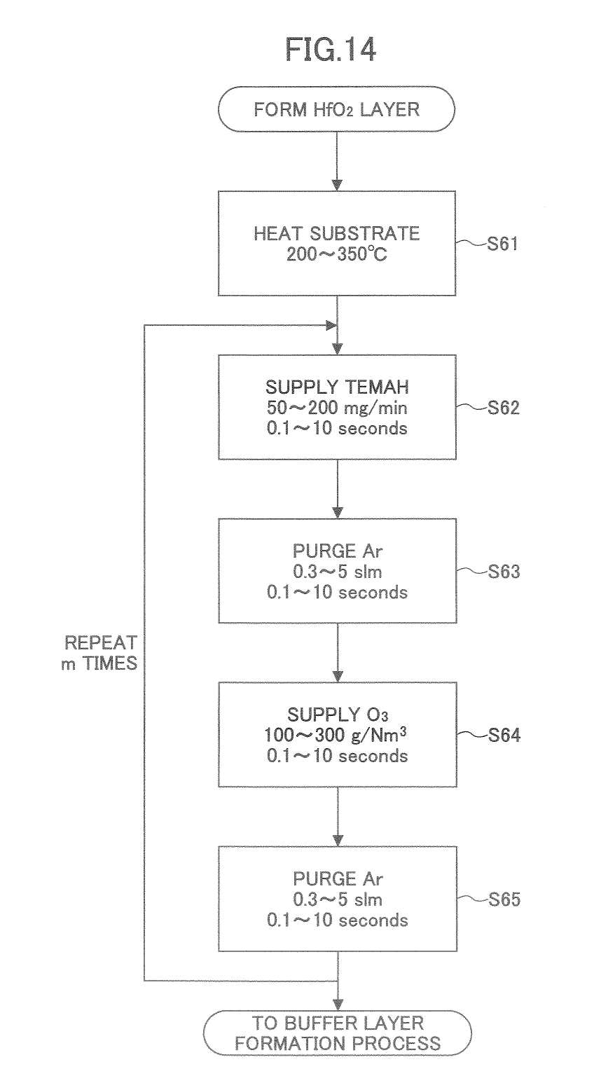

First, as shown in FIG. 14, place the substrate on which the transistor structure 6 and the lower electrode 22 are formed in the process container 31, and heat the substrate at 200 to 350° C. (step S61). Next, the first raw material switching valve 35A is opened so as to introduce tetrakis ethyl methyl amino hafnium (TEMAH) containing Hf as the first process gas into the process container 31. At this time, the second raw material switch valve 35B is closed so as to be in the state shown in FIG. 3(A). Accordingly, the TEMAH flows on the substrate, and Hf is adsorbed onto the substrate (the lower electrode 22) (step S62). At this times it is preferable that the flow rate of the TEMAH is adjusted to 50 to 200 mg/min and the time of supplying the TEMAH is set to 0.1 to 10 seconds.

When the supply of the TEMAH is completed in step S62, subsequently, a process of purging the TEMAH in the process container 31 is performed (step S63). In this process, Ar as an inert gas is supplied to the process container 31 and is exhausted from the exhaust ports 34A and 34B so as to evacuate the TEMAH. It is preferable that the flow rate of Ar is 0.3 to 5 slm and the purge time is 0.1 to 10 seconds. Thereby, the film thickness can be controlled with good accuracy.

After the purge by Ar is completed, next, the second raw material switch valve 35B is opened so as to introduce O₃ as the second process gas B into the process container 31. At this time, the first raw material switch valve 35A is closed so as to be in the state shown in FIG. 3(B). Accordingly, O₃ flows on the substrate, and Hf adsorbed on the substrate and O₃ react each other, thereby HfO is produced on the substrate (step S64). At this time, it is preferable that the flow rate of O₃ is adjusted to 100 to 300 g/Nm³ and a time of supplying O₃ is 0.1 to 10 seconds.

After the supply of O₃ is completed in step S64, a process of purging O₃ and reaction byproducts in the process container 31 is performed (step S65). In this process, Ar is supplied to the process container 31 as an inactive gas and is exhausted from the exhaust ports 34A and 34B. It is preferable that the flow rate of Ar is 0.3 to 5 slm and the purge time is 0.1 to 10 seconds.

Here, the process of step S62 to step S65 corresponds to one cycle of ALD method. Accordingly, in the present embodiment, the process of step S62 to step S65 is repeated m times. Specifically, tow times to form the multi-layer structure shown in FIG. 10, seven times to form the multi-layer structure shown in FIG. 11, and five times to form the multi-layer structure shown in FIG. 12.

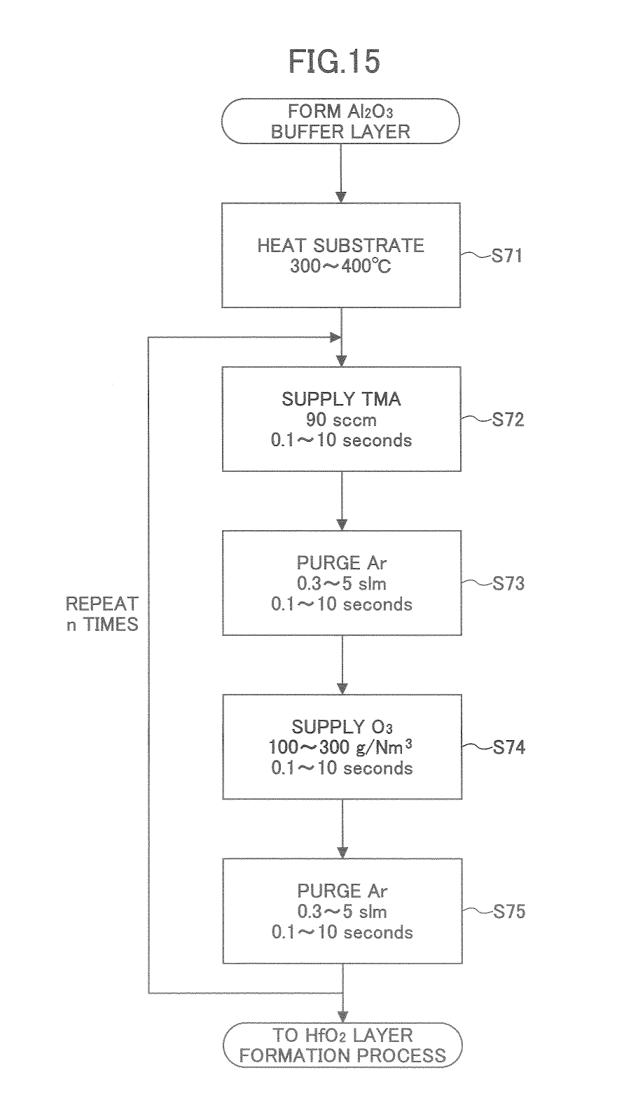

After repeating the formation process of HfO₂ for predetermined cycles, then, it proceeds to formation process of the buffer layer 38. In the formation process of the buffer layer 38, an amorphous state Al₂O₃ layer is formed as a buffer layer on the previously formed HfO₂ layer. FIG. 15 is a flowchart of a process of forming the Al₂O₃ layer as a buffer layer.

First, a substrate in the process container 31 is heated at 300 to 400° C. (step S71). Next, the first raw material switching valve 35A is opened so as to introduce trimethyl aluminum (TEA) containing Al as the first process gas A into the process container 31. At this time, the second raw material switch valve 35B is closed so as to be in the state shown in FIG. 3(A). Accordingly, the TMA flows on the substrate, and Al is adsorbed onto the substrate (on the HfO₂ layer) (step S72). At this time, it is preferable that the flow rate of the TMA is adjusted to 90 sccm and the time of supplying the TMA is set to 0.1 to 10 seconds. A raw material containing organic Al other than TMA may be used as the first process gas A.

When the supply of the TMA is completed in step S72, subsequently, a process of purging the TMA in the process container 31 is performed (step S73). In this process, Ar as an inert gas is supplied to the process container 31 and is high-speed exhausted from the exhaust ports 34A and 34B. It is preferable that the flow rate of Ar is 0.3 to 5 slm and the purge time is 0.1 to 10 seconds.

After the purge by Ar is completed, next, the second raw material switch valve 35B is opened so as to introduce O₃ as the second process gas B into the process container 31. At this time, the first raw material switch valve 35A is closed so as to be in the state shown in FIG. 3(B). Accordingly, O₃ flows on the substrate, and Al adsorbed on the substrate and O₃ react each other, thereby Al₂O₃ is produced on the substrate (step S74). At this time, it is preferable that the flow rate of O₃ is adjusted to 100 to 300 g/Nm³ and a time of supplying O₃ is 0.1 to 10 seconds.

After the supply of O₃ is completed in step S74, a process of purging O₃ and reaction byproducts in the process container 31 is performed (step S75). In this process, Ar is supplied to the process container 31 as an inactive gas and is high-speed exhausted from the exhaust ports 34A and 34B. It is preferable that the flow rate of Ar is 0.3 to 5 slm and the purge time is 0.1 to 10 seconds.

Here, the process of step S72 to step S75 corresponds to one cycle of an ALD method. Accordingly, in the present embodiments the process of step S72 to step S75 is repeated n times. Specifically, two times to form the multi-layer structure shown in FIG. 19, three times to form the multi-layer structure shown in FIG. 11, and one time to form the multi-layer structure shown in FIG. 12.

As mentioned above, when the formation of the Al₂O₃ buffer layer 38 is completed, the process or step S61 to S65 shown in FIG. 14 is repeated m times again. Subsequently, the buffer layer 38 is formed by performing the process of steps S71 to S75 n times. By repeating the above mentioned process X times, the HfO₂ thin film 36 of a predetermined thickness 36 is formed by repeating the above-mentioned process X times.

After completion of the formation of the HfO₂ thin film 36, the HfO₂ thin film capacitor is completed by forming the upper electrode 24 on the last formed HfO₂ layer 36B. It should be noted that the lower electrode 22 and the upper electrode 24 are not limited to a TiN film, and may be formed by various electrically conductive materials.

It should be noted that the stacked film HfAlO (HfO₂/Al₂O₃) generated by the present invention can be used as a gate insulation film of a CMOS transistor. When using in a gate electrode, the interface Si/SiO is controlled smoothly by forming an intermediate layer (inter layer) of 3 to 10 Å by an extremely thin silicon oxide film directly on a substrate surface. The stacked film (HfO₂/Al₂O₃) according to the present invention is formed thereon with 10 to 50 Å so as to use as a gate electrode. Thereby, a low leak current can be achieved and moving speed of electrons can be increased.

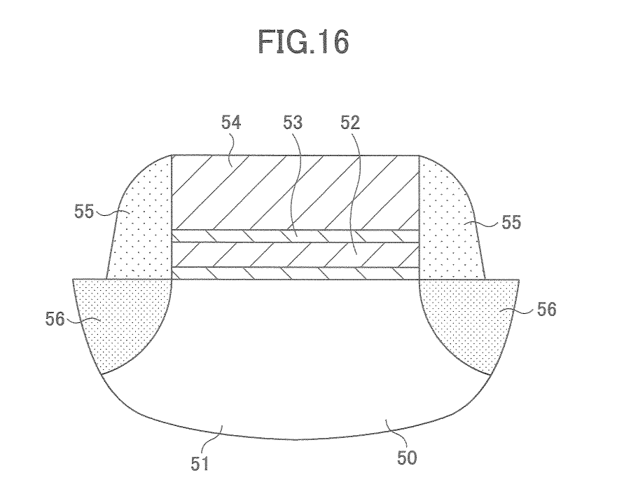

FIG. 16 is an illustration showing an outline structure of a transistor in which the above-mentioned gate electrode is formed. An intermediate layer (inter layer) 51, which is an extremely thin oxide film, is formed on the silicon (Si) substrate 50, and the stacked film (HfAlO) 52 according to the present invention is formed thereon as a high-dielectric constant film. The surface of the stacked film (HfAlO) 52 is nitrided to form a nitride film 53, and a polysilicon (PolySi) or a poly silicon/W (polymetal) is produced as a gate electrode 54 thereon. Oxide silicon layers (SiO₂) 55 are formed as spacers on side portions of these films, and wells 56 (diffusion areas) are formed as a source area and a drain layer in the Si substrate 50 underneath.

The oxide film 51 of the intermediate layer (inter layer) can be formed by a processing apparatus (UV-RF) disclosed in the previously filed International Patent Application (International Publication Number WO3/063220) filed by the present applicant.

Additionally, an impurity concentration of carbon in the high-dielectric metal oxide film formed by the method according to the present invention was E+21 atoms/cm³, and a very low impurity concentration was attained.

The present invention is not limited to the above-mentioned specifically disclosed embodiments, and various variations and modifications may be made without departing from the scope of the present invention.

### INDUSTRIAL APPLICABILITY

The present invention is applicable to a thin film capacitor provided in a circuit formed in a semiconductor substrates.

1. A thin film capacitor formed with a zirconium oxide or a hafnium oxide as a dielectric material, comprising:
a lower electrode made of a conductive material;
a first dielectric layer formed on the lower electrode;
a buffer layer formed on the first dielectric layer;
a second dielectric layer formed on the buffer layer; and
an upper layer formed on the second dielectric layer and made of a conductive material,
wherein said first and second dielectric layers are formed by one of the zirconium oxide and the hafnium oxide.

2. The thin film capacitor as claimed in claim 1, wherein said buffer layer is formed by an amorphous material.

3. The thin film capacitor as claimed in claim 2, wherein said buffer layer is formed by a material selected from Al₂O₃, HfO₂, Ta₂O₅ and amorphous ZrO₂.

4. The thin film capacitor as claimed in any one of claims 1 through 3, wherein said first and second dielectric layers have the same thickness, and said buffer layer is thinner than said first and second dielectric layers.

5. The thin film capacitor as claimed in claim 4, wherein said first and second dielectric layers are formed by a zirconium oxide, a thickness of each of said first and second dielectric layers is 1 to 70 Å, and a thickness of said buffer layer is 1 to 20 Å.

6. The thin film capacitor as claimed in claim 1, wherein said first dielectric layer, said buffer layer and said second dielectric layer are formed in consecutive processes.

7. A thin film capacitor formed with a zirconium oxide or a hafnium oxide as a dielectric material, comprising:
a lower electrode made of a conductive material;
an upper electrode made of a conductive material;
a plurality of dielectric layers formed between the lower electrode and the upper electrode; and
a buffer layer made of an amorphous material formed between adjacent upper and lower layers among the plurality of dielectric layers,
wherein said plurality of dielectric layers is formed by one of the zirconium oxide and the hafnium oxide.

8. The thin film capacitor as claimed in claim 7, wherein said buffer layer is formed by a material selected from Al₂O₃, HfO₂, Ta₂O₅ and amorphous ZrO₂.

9. A forming method of a thin film capacitor using a zirconium oxide or a hafnium oxide as a dielectric material, comprising:
forming a lower electrode made of a conductive material;
forming a first dielectric layer by one of the zirconium oxide and the hafnium oxide on the lower electrode;
forming a buffer layer of a predetermined thickness on the first dielectric layer;
forming a second dielectric layer of a predetermined thickness on the buffer layer by using a material the same as said first dielectric layer; and
forming an upper electrode made of a conductive material on the second dielectric layer.

10. The forming method of a thin film capacitor as claimed in claim 9, wherein the formation of said first dielectric layer, the formation of said buffer layer and the formation of said second dielectric layer are performed consecutively in a film deposition process according to an ALD method.

11. A computer readable storage medium storing a program causing a computer to perform a forming method of a thin film capacitor, comprising:
forming a lower electrode made of a conductive material;
forming a first dielectric layer by one of a zirconium oxide and a hafnium oxide on the lower electrode;
forming a buffer layer of a predetermined thickness on the first dielectric layer;
forming a second dielectric layer of a predetermined thickness on the buffer layer by using a material the same as said first dielectric layer; and
forming an upper electrode made of a conductive material on the second dielectric layer.

12. The computer readable storage medium as claimed in claim 11, wherein said program causes to perform the formation of said first dielectric layer, the formation of said buffer layer and the formation of said second dielectric layer consecutively in a film deposition process according to an ALD method.

13. A forming method of a thin film capacitor using a zirconium oxide or a hafnium oxide as a dielectric material, comprising:
forming a lower electrode made of a conductive material;
forming a dielectric layer by one of a zirconium oxide and a hafnium oxide on the lower electrode;
forming a buffer layer of a predetermined thickness on the dielectric layer;
forming a multi-layer dielectric layer of a predetermined thickness by repeating the step of forming said dielectric layer and the step of forming said buffer layer for a predetermined number of times; and
forming an upper electrode made of a conductive material on the multi-layer dielectric layer.

14. The forming method of a thin film capacitor as claimed in claim 13, wherein the formation of said dielectric layer and the formation of said buffer layer are consecutively performed in a film deposition process according to an ALD method.

15. A computer readable storage medium storing a program for causing a computer to perform a forming method of a thin film capacitor, comprising:
forming a lower electrode made of a conductive material;
forming a dielectric layer by one of a zirconium oxide and a hafnium oxide on the lower electrode;
forming a buffer layer of a predetermined thickness on the dielectric layer;
forming a multi-layer dielectric layer of a predetermined thickness by repeating the step of forming said dielectric layer and the step of forming said buffer layer for a predetermined number of times; and
forming an upper electrode made of a conductive material on the multi-layer dielectric layer.

16. The computer readable storage medium as claimed in claim 15, wherein said program causes the formation of said dielectric layer and the formation of said buffer layer to be performed consecutively in a film deposition process according to an ALD method.
